(19) United States
(12) Patent Application Publication
(10) Pub. No.: US 2024/0186233 A1
(43) Pub. Date: Jun. 6, 2024

(54) PACKAGING STRUCTURE AND PACKAGING METHOD

(71) Applicant: Semiconductor Manufacturing International (Shanghai) Corporation, Shanghai (CN)

(72) Inventor: Jisong JIN, Shanghai (CN)

(73) Assignee: Semiconductor Manufacturing International (Shanghai) Corporation, Shanghai (CN)

(21) Appl. No.: 18/515,472

(22) Filed: Nov. 21, 2023

(30) Foreign Application Priority Data
Dec. 6, 2022 (CN) 202211556479.8

(51) Int. Cl. H01L 23/498; H01L 23/00; H01L 23/31; H01L 23/48

(52) U.S. Cl. CPC H01L 23/49838; H01L 23/3128; H01L 23/481; H01L 23/49816; H01L 23/49822; H01L 24/13; H01L 24/16; H01L 24/24; H01L 24/32; H01L 24/73; H01L 24/81; H01L 2224/13111; H01L 2224/16245; H01L 2224/24175; H01L 2224/32245; H01L 2224/73204; H01L 2224/81005; H01L 2924/181

(57) ABSTRACT

A packaging structure and a packaging method are provided. The packaging method includes: providing a carrier; forming a first redistribution structure on the carrier, the first redistribution structure including a first area and a second area; forming a conductive pillar on the first redistribution structure in the first area, the conductive pillar being electrically connected to the first redistribution structure; providing a device chip, including a first side and a second side opposite to the first side; bonding the second side of the device chip to the first redistribution structure in the second area, the device chip being electrically connected to the first redistribution structure; providing a substrate including a bonding surface; and bonding the first side of the device chip and the conductive pillar to the bonding surface, the device chip being electrically connected to the substrate, and the conductive pillar being electrically connected to the substrate.

### CROSS REFERENCE TO RELATED APPLICATIONS

This application is based on and claims priority to Chinese patent Application No. 202211556479.8, filed Dec. 6, 2022, the entire content of which is incorporated herein by reference.

### TECHNICAL FIELD

The disclosure relates to the technical field of semiconductor packaging, and in particular to a packaging structure and a packaging method.

### BACKGROUND

For monolithic chip sizes, conventional chip manufacturing technologies are being pushed to their limits. However, applications are hungry for the ability to use the latest technology to achieve large size integrated circuits, and it is a great challenge to enable high-speed and small-volume interconnection between chips.

One current solution is to use smaller integrated circuits with Si bridge chips embedded in the silicon substrate to enable the interconnection between chips through the Si bridge chip, thereby providing heterogeneous chip packaging.

However, the current packaging structures are complex in structure, and the integration level between the chips still needs to be improved.

### SUMMARY

The present disclosure relates to a packaging structure and a packaging method to improve the integration level of the packaging structure.

In an aspect of the disclosure, a packaging structure is provided. The packaging structure may include:
a substrate, including a bonding surface; a device chip, including a first side and a second side opposite to the first side, the first side being bonded to the bonding surface and electrically connected to the substrate; a conductive pillar, bonded to the bonding surface at a side of the device chip and electrically connected to the substrate; and a first redistribution structure, located on the second side of the device chip and a side of the conductive pillar facing away from the bonding surface, the first redistribution structure being electrically connected to the second side of the device chip and the conductive pillar.

In an implementation, the first side is a front side of the chip, and the second side is a back side of the chip.

In an implementation, the packaging structure further includes: a packaging layer, located on the first redistribution structure and covering the device chip and side walls of the conductive pillar.

In an implementation, the packaging structure further includes: a first conductive bump, located between the device chip and the first redistribution structure and electrically connecting the device chip to the first redistribution structure.

In an implementation, the packaging structure further includes: a first sealing layer, filled in a gap between the adjacent first conductive bumps and covering the first conductive bump.

In an implementation, the packaging structure further includes: a second conductive bump, located between the device chip and the substrate and between the conductive pillar and the substrate, electrically connecting the device chip to the substrate and electrically connecting the conductive pillar to the substrate.

In an implementation, the packaging structure further includes: a second redistribution structure, located on the first side of the device chip and a side of the conductive pillar facing the substrate, the second redistribution structure being electrically connected to the device chip and the conductive pillar.

In an implementation, the packaging structure further includes: a second sealing layer, filled in a gap between the adjacent second conductive bumps and covering the second conductive bump.

In an implementation, the packaging structure further includes: a third conductive bump, located on a surface of the substrate facing away from the bonding surface, the third conductive bump being used for enabling electrical connection between the packaging structure and an external circuit.

In an implementation, the first redistribution structure includes one or more first redistribution layers; and the second redistribution structure includes one or more second redistribution layers.

In another aspect of the disclosure, a packaging method is provided. The method may include:
providing a carrier; forming a first redistribution structure on the carrier, the first redistribution structure including a first area and a second area; forming a conductive pillar on the first redistribution structure in the first area, the conductive pillar being electrically connected to the first redistribution structure; providing a device chip, including a first side and a second side opposite to the first side; bonding the second side of the device chip to the first redistribution structure in the second area, the device chip being electrically connected to the first redistribution structure; providing a substrate including a bonding surface; and bonding, after forming the conductive pillar on the first redistribution structure in the first area and bonding the second side of the device chip to the first redistribution structure in the second area, the first side of the device chip and the conductive pillar to the bonding surface, the device chip being electrically connected to the substrate, and the conductive pillar being electrically connected to the substrate.

In an implementation, in the step of providing the device chip, the first side is a front side of the chip, and the second side is a back side of the chip.

In an implementation, the packaging method further includes: forming, after forming the conductive pillar on the first redistribution structure in the first area and bonding the second side of the device chip to the first redistribution structure in the second area and before bonding the first side of the device chip and the conductive pillar to the bonding surface, a packaging layer covering side walls of the device chip and the conductive pillar on the first redistribution structure.

In an implementation, the step of bonding the second side of the device chip to the first redistribution structure in the second area includes: forming a first conductive bump on any one or both of the first redistribution structure in the second area and the second side of the device chip; and bonding the second side of the device chip to the first redistribution structure in the second area through the first conductive bump, the first conductive bump electrically connecting the device chip to the first redistribution structure.

In an implementation, after bonding the second side of the device chip to the first redistribution structure in the second area and before bonding the first side of the device chip and the conductive pillar to the bonding surface, the packaging method further includes: filling a first sealing layer in a gap between the adjacent first conductive bump, the first sealing layer covering the first conductive bump.

In an implementation, the step of bonding the first side of the device chip and the conductive pillar to the bonding surface includes: forming a second conductive bump on the first side of the device chip and the conductive pillar, and/or, on the bonding surface of the substrate; and enabling bonding of the device chip to the substrate and bonding of the conductive pillar to the substrate through the second conductive bump, the second conductive bump electrically connecting the device chip to the substrate and electrically connecting the conductive pillar to the substrate.

In an implementation, after forming the conductive pillar on the first redistribution structure in the first area and bonding the second side of the device chip to the first redistribution structure in the second area and before bonding the first side of the device chip and the conductive pillar to the bonding surface, the packaging method further includes: forming a second redistribution structure on the first side of the device chip, the second redistribution structure being electrically connected to the device chip and the conductive pillar.

In an implementation, after bonding the first side of the device chip and the conductive pillar to the bonding surface, the packaging method further includes: filling a second scaling layer in a gap between the adjacent second conductive bump, the second sealing layer covering the second conductive bump.

In an implementation, the packaging method further includes: removing, after bonding the first side of the device chip and the conductive pillar to the bonding surface, the carrier.

In an implementation, after bonding the first side of the device chip and the conductive pillar to the bonding surface, the packaging method further includes: forming a third conductive bump on a surface of the substrate facing away from the bonding surface, the third conductive bump being used for enabling electrical connection between the packaging structure and an external circuit.

Compared with the prior art, the present disclosure has the following advantages:

In the packaging structure provided by an implementation of the disclosure, the device chip includes the first side and the second side opposite to the first side, and the first side is bonded to the bonding surface and electrically connected to the substrate; the conductive pillar is bonded to the bonding surface at the side of the device chip and electrically connected to the substrate; the first redistribution structure is located on the second side of the device chip and the side of the conductive pillar facing away from the bonding surface; and the first redistribution structure is electrically connected to the second side of the device chip and the conductive pillar.

In the implementation of the disclosure, the first side of the device chip is bonded to the bonding surface to enable electrical connection between the first side of the device chip and the substrate, the device chip is electrically connected to the conductive pillar through the first redistribution structure located on the second side of the device chip, and the conductive pillar is electrically connected to the substrate so as to enable electrical connection between the second side of the device chip and the substrate, so that the first side and the second side of the device chip opposite to the first side can both be electrically connected to the substrate, and accordingly the first side and the second side of the device chip can both be electrically connected to an external circuit through the substrate, thereby improving the integration level of the packaging structure.

In the packaging method provided by an implementation of the disclosure, the conductive pillar is formed on the first redistribution structure in the first area, and the conductive pillar is electrically connected to the first redistribution structure; the second side of the device chip is bonded to the first redistribution structure in the second area, and the device chip is electrically connected to the first redistribution structure; the packaging layer covering the side walls of the device chip and the conductive pillar is formed on the first redistribution structure; and the first side of the device chip and the conductive pillar are bonded to the bonding surface, the device chip is electrically connected to the substrate, and the conductive pillar is electrically connected to the substrate.

In the implementation of the disclosure, the first side of the device chip is bonded to the bonding surface to enable electrical connection between the first side of the device chip and the substrate, the device chip is electrically connected to the conductive pillar through the first redistribution structure located on the second side of the device chip, and the conductive pillar is electrically connected to the substrate so as to enable electrical connection between the second side of the device chip and the substrate, so that the first side and the second side of the device chip opposite to the first side can both be electrically connected to the substrate, and accordingly the first side and the second side of the device chip can both be electrically connected to an external circuit through the substrate, thereby improving the integration level of the packaging structure.

### BRIEF DESCRIPTION OF THE DRAWINGS

FIG. 1 is a schematic structural view of a packaging structure according to an implementation of the disclosure; and

FIG. 2 to FIG. 9 are schematic structural views corresponding to steps of a packaging method according to an implementation of the disclosure.

### DETAILED DESCRIPTION

Traditionally, only the front side of the two opposite sides of the chip is electrically connected to an external circuit. With the back side power delivery network (BSPDN) technology, the back side of the chip is also formed with pads for electrical connection to the external circuit, for example, as in the document 10.1109/TED.2019.2954301. However, at present, there is no method to electrically lead out the back side of the chip so as to electrically connect both the front side and back side of the chip to the external circuit, which makes it difficult to improve the integration level of packaging.

In order to address the technical problems, an implementation of the disclosure provides a packaging structure, including: a device chip, including a first side and a second side opposite to the first side, the first side being bonded to a bonding surface and electrically connected to a substrate; a conductive pillar, bonded to the bonding surface at a side of the device chip and electrically connected to the substrate; and a first redistribution structure, located on the second side of the device chip and a side of the conductive pillar facing away from the bonding surface, the first redistribution structure being electrically connected to the second side of the device chip and the conductive pillar. In the implementation of the disclosure, the first side of the device chip is bonded to the bonding surface to enable electrical connection between the first side of the device chip and the substrate, the device chip is electrically connected to the conductive pillar through the first redistribution structure located on the second side of the device chip, and the conductive pillar is electrically connected to the substrate so as to enable electrical connection between the second side of the device chip and the substrate, so that the first side and the second side of the device chip opposite to the first side can both be electrically connected to the substrate, and accordingly the first side and the second side of the device chip can both be electrically connected to an external circuit through the substrate, thereby improving the integration level of the packaging structure.

To make the foregoing objectives, features, and advantages of the disclosure more apparent and easier to understand, specific implementations of the disclosure are described in detail below with reference to the accompanying drawings.

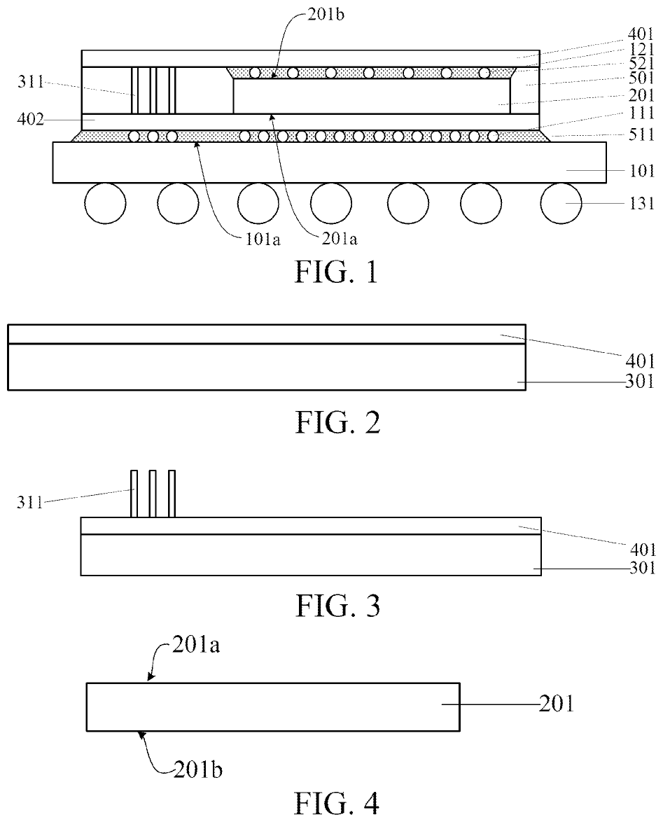

FIG. 1 is a schematic structural view of a packaging structure according to an implementation of the disclosure.

The packaging structure includes: a substrate 101, including a bonding surface 101a; a device chip 201, including a first side 201a and a second side 201b opposite to the first side, the first side 201a being bonded to the bonding surface 101a and electrically connected to the substrate 101; a conductive pillar 311, bonded to the bonding surface 101a at a side of the device chip 201 and electrically connected to the substrate 101; and a first redistribution structure 401, located on the second side 201b of the device chip 201 and a side of the conductive pillar 311 facing away from the bonding surface 101a, the first redistribution structure 401 being electrically connected to the second side 201b of the device chip 201 and the conductive pillar 311.

The substrate 101 is used for enabling bonding to the device chip 201 and bonding to the conductive pillar 311 so as to enable packaging integration and electrical integration of the device chip 201, the conductive pillar 311 and the substrate 101. The substrate 101 is also used for providing a process operation basis for enabling bonding to the device chip 201 and bonding to the conductive pillar 311.

Specifically, the bonding surface 101a of the substrate 101 is a process operation platform.

In this implementation, the substrate 101 is a PCB (printed circuit board). The device chip 201 is used for electrical connection to the substrate 101, so as to form the corresponding packaging structure to enable corresponding functions.

In this implementation, the first side 201a of the device chip 201 is bonded to the bonding surface 101a and electrically connected to the substrate 101 to enable electrical connection between the first side 201a of the device chip 201 and the substrate 101.

In this implementation, the first side 201a is a front side of the chip to accordingly enable electrical connection between the front side of the chip and the substrate 101.

The front side of the chip is a side facing the device in the chip.

In an example, the first side 201a of the device chip 201 is bonded to the bonding surface 101a of the substrate 101 to enable signal communication between the device chip 201 and the substrate 101.

The conductive pillar 311 is used for enabling electrical connection between the first redistribution structure 401 and the substrate 101, thereby enabling electrical connection between the device chip 201 and the substrate 101 through the first redistribution structure 401.

In this implementation, a material of the conductive pillar 311 is copper, i.e., the conductive pillar 311 is a copper pillar. In other implementations, the material of the conductive pillar may be other metal materials, for example, one or more of tin, copper, aluminum, tungsten, cobalt, nickel, titanium, tantalum, titanium nitride and tantalum nitride.

In this implementation, the number of the conductive pillars 311 is plural to improve the electrical connection performance between the conductive pillar 311 and the substrate 101.

The first redistribution structure 401 is used for enabling electrical connection between the second side 201b of the device chip 201 and the conductive pillar 311, thereby electrically leading out the second side 201b of the device chip 201.

In this implementation, the second side 201b is a back side of the chip, thereby enabling electrical connection between the back side of the device chip 201 and the substrate 101.

The back side of the chip is a side facing away from the device in the chip.

In this implementation, the first side 201a of the device chip 201 is bonded to the bonding surface 101a to enable electrical connection between the first side 201a of the device chip 201 and the substrate 101, the device chip 201 is electrically connected to the conductive pillar 311 through the first redistribution structure 401 located on the second side 201b of the device chip 201, and the conductive pillar 311 is electrically connected to the substrate 101 so as to enable electrical connection between the second side 201b of the device chip 201 and the substrate 101, so that the first side 201a and the second side 201b of the device chip 201 opposite to the first side can both be electrically connected to the substrate 101, and accordingly the first side 201a and the second side 201b of the device chip 201 can both be electrically connected to an external circuit through the substrate 101, thereby improving the integration level of the packaging structure.

During the actual process, this implementation is particularly applicable to the case where a buried power rail (BPR) structure and a power delivery network (PDN) structure are used, which has high requirements for chip size and integration level.

In an example, the first side 201a of the device chip 201 is bonded to the bonding surface 101a to enable signal communication between the first side 201a of the device chip 201 and the substrate 101. The device chip 201 is electrically connected to the conductive pillar 311 through the first redistribution structure 401 located on the second side 201b of the device chip 201, and the conductive pillar 311 is electrically connected to the substrate 101 so as to enable electrical connection between the second side 201b of the device chip 201 and the substrate 101, thereby enabling power supply to the device chip 201 through the substrate 101.

In this implementation, a second interconnection structure is formed in the first redistribution structure 401, and the conductive pillar 311 is electrically connected to the device chip 201 through the second interconnection structure.

In this implementation, a material of the first redistribution structure 401 is a metal material, for example, one or more of copper, aluminum, tungsten, cobalt, nickel, titanium, tantalum, titanium nitride and tantalum nitride.

In this implementation, the first redistribution structure 401 may include one or more redistribution layers.

In this implementation, the first redistribution structure 401 including one redistribution layer will be described In an example.

In this implementation, the first redistribution structure 401 is bonded to the device chip 201 and the conductive pillar 311, so the device chip 201 and the conductive pillar 311 can be sealed in the same step as the first redistribution structure 401, which is beneficial to improve the process efficiency.

It would be appreciated that in this implementation, the packaging structure further includes: a first conductive bump 121, located between the device chip 201 and the first redistribution structure 401 and electrically connecting the device chip 201 to the first redistribution structure 401.

The first conductive bump 121 is used for enabling electrical connection between the first redistribution structure 401 and the device chip 201.

In this implementation, a material of the first conductive bump 121 includes one or more of tin, copper, aluminum, tungsten, cobalt, nickel, titanium, tantalum, titanium nitride and tantalum nitride. In an example, the material of the first conductive bump 121 is tin.

For example, the first conductive bump 121 may be C4 (Controlled Collapse Chip Connection), and has excellent electrical properties and thermal characteristics. Moreover, in a case of the same pitch between the first conductive bumps 121, the I/O number can be very high, and not limited by the size of the redistribution structure. Besides, the first conductive bump is suitable for mass production, and the size and weight are greatly reduced.

In other implementations, the first conductive bump may be a uBump.

In this implementation, the packaging structure further includes: a first sealing layer 521, filled in a gap between the adjacent first conductive bumps 121 and covering the first conductive bump 121.

The first sealing layer 521 is used for enabling sealing between the device chip 201 and the first redistribution structure 401, and also used for sealing the first conductive bump 121. In an example, the first sealing layer 521 is an underfill.

In this implementation, the packaging structure further includes: a packaging layer 501, located on the first redistribution structure 401 and covering side walls of the device chip 201 and the conductive pillar 311.

The first packaging layer 501 is used for protecting structures of the device chip 201, the conductive pillar 311 and the first redistribution structure 401, and also plays a sealing role to isolate the device chip 201, the conductive pillar 311 and the first redistribution structure 401 from an external environment.

In this implementation, a material of the packaging layer 501 is a molding material, for example, epoxy resin. The epoxy resin has the advantages of low shrinkage, good binding property, good corrosion resistance, excellent electrical properties, low cost, etc., and is beneficial to improve the packaging effect of the packaging layer 501 on the device chip 201, the conductive pillar 311 and the first redistribution structure 401. In other implementations, the packaging layer may be made of other appropriate packaging materials.

In this implementation, the packaging structure further includes: a second redistribution structure 402, located on the first side 201a of the device chip 201 and a side of the conductive pillar 311 facing the substrate 101, the second redistribution structure 402 being electrically connected to the device chip 201 and the conductive pillar 311.

Specifically, the second redistribution structure 402 is located on the first side 201a of the device chip 201, the side of the conductive pillar 311 facing the substrate 101, and a side of the packaging layer 501 facing the substrate 101.

The second redistribution structure 402 is used for enabling electrical connection between the device chip 201, the conductive pillar 311 and an external circuit,
and also used for redistributing interconnection positions of the device chip 201 and the conductive pillar 311 with the outside.

In this implementation, the second redistribution structure 402 includes one or more second redistribution layers.

In this implementation, the second redistribution structure 402 including one redistribution layer will be described In an example.

In this implementation, a material of the second redistribution structure 402 is a metal material, for example, one or more of copper, aluminum, tungsten, cobalt, nickel, titanium, tantalum, titanium nitride and tantalum nitride.

In other implementations, the second redistribution structure may also be omitted in the packaging structure based on actual process demands.

In this implementation, the packaging structure further includes: a second conductive bump 111, located between the device chip 201 and the substrate 101 and between the conductive pillar 311 and the substrate 101, electrically connecting the device chip 201 to the substrate 101, and electrically connecting the conductive pillar 311 to the substrate 101.

The second conductive bump 111 is used for enabling electrical connection between the substrate 101 and the device chip 201 and enabling electrical connection between the conductive pillar 311 and the substrate 101.

In an example, the second conductive bump 111 is located between the second redistribution structure 402 and the substrate 101, which is beneficial to improve the density of the second conductive bumps 111, thereby improving the interconnection density between the device chip 201 and the substrate 101 and the interconnection density between the conductive pillar 311 and the substrate 101. Accordingly, the second conductive bump 111 is used for enabling electrical connection between the second redistribution structure 402 and the substrate 101.

In this implementation, a material of the second conductive bump 111 includes one or more of tin, copper, aluminum, tungsten, cobalt, nickel, titanium, tantalum, titanium nitride and tantalum nitride. In an example, the material of the second conductive bump 111 is tin.

For example, the second conductive bump 111 may be C4 (Controlled Collapse Chip Connection), and has excellent electrical properties and thermal characteristics. Moreover, in a case of the same pitch between the second conductive bumps, the I/O number can be very high, and not limited by the size of the redistribution structure. Besides, the second conductive bump is suitable for mass production, and the size and weight are greatly reduced.

In other implementations, the second conductive bump may be a uBump.

In this implementation, the packaging structure further includes: a second sealing layer 511, filled in a gap between the adjacent second conductive bumps 111 and covering the second conductive bump 111.

The second sealing layer 511 is used for enabling sealing between the device chip 201 and the substrate 101 and sealing between the conductive pillar 311 and the substrate 101, and also used for sealing the second conductive bump 111.

More specifically, in this implementation, the second sealing layer 511 is used for enabling sealing between the second redistribution structure 402 and the substrate 101, and also used for sealing the second conductive bump 111.

In this implementation, the second sealing layer 511 is an underfill.

In this implementation, the packaging structure further includes: a third conductive bump 131, located on a surface of the substrate 101 facing away from the bonding surface 101a. The third conductive bump 131 is used for enabling electrical connection between the packaging structure and an external circuit.

The electrical connection between the packaging structure and the external circuit is enabled through the third conductive bump 131, so that the front side and the back side of the device chip 201 are both electrically connected to the external circuit.

In this implementation, a material of the third conductive bump 131 includes one or more of tin, copper, aluminum, tungsten, cobalt, nickel, titanium, tantalum, titanium nitride and tantalum nitride. In an example, the material of the third conductive bump 131 is tin.

For example, the third conductive bump 131 may be C4 (Controlled Collapse Chip Connection), and has excellent electrical properties and thermal characteristics. Moreover, in a case of the same pitch between the third conductive bumps 131, the I/O number can be very high, and not limited by the size of the redistribution structure. Besides, the third conductive bump is suitable for mass production, and the size and weight are greatly reduced.

In other implementations, the third conductive bump may be a ball grid array (BGA) structure.

The packaging structure in this implementation may be formed by the packaging method of the implementation of the disclosure or by other methods.

FIG. 2 to FIG. 9 are schematic structural views corresponding to steps of a packaging method according to an implementation of the disclosure. Referring to FIG. 2, a carrier 301 is provided.

The carrier 301 is used for providing a process operation platform for subsequent packaging steps. The carrier 301 is also used for providing carrying and supporting functions for subsequent process steps.

More specifically, the carrier 301 is used for carrying a first redistribution structure subsequently.

In this implementation, the carrier 301 is a carrier wafer. In other implementations, the carrier may also be other types of bases. In this implementation, a material of the carrier may include one or more of silicon, glass, silicon oxide and aluminum oxide.

Still referring to FIG. 2, a first redistribution structure 401 is formed on the carrier 301. The first redistribution structure 401 includes a first area (not shown) and a second area (not shown).

In the first redistribution structure 401, the first area is used for forming a conductive pillar so as to enable electrical connection to the conductive pillar. The second area is used for bonding the device chip so as to enable electrical connection to the device chip.

More specifically, in this implementation, the first redistribution structure 401 is used for enabling electrical connection between the second side of the device chip and the conductive pillar, thereby electrically leading out the second side of the device chip.

In this implementation, the first redistribution structure 401 is temporarily bonded to the carrier 301, so that the carrier 301 can be removed after enabling bonding of the conductive pillar to the substrate and bonding of the device chip to the substrate subsequently, and the difficulty in removal of the carrier 301 is reduced.

In this implementation, the first redistribution structure 401 is temporarily bonded to the carrier 301, thereby making preparations for subsequent bonding of the device chip and the conductive pillar.

In this implementation, a second interconnection structure (not shown) is formed in the first redistribution structure 401, and the conductive pillar 311 is electrically connected to the device chip through the second interconnection structure.

In this implementation, a material of the first redistribution structure 401 is a metal material, for example, one or more of copper, aluminum, tungsten, cobalt, nickel, titanium, tantalum, titanium nitride and tantalum nitride.

In this implementation, the first redistribution structure 401 may include one or more redistribution layers.

In this implementation, the first redistribution structure 401 including one redistribution layer will be described In an example.

Referring to FIG. 3, a conductive pillar 311 is formed on the first redistribution structure 401 in the first area. The conductive pillar 311 is electrically connected to the first redistribution structure 401.

The conductive pillar 311 is used for enabling electrical connection between the first redistribution structure 401 and the substrate, thereby enabling electrical connection between the device chip and the substrate through the first redistribution structure 401.

In this implementation, a material of the conductive pillar 311 is copper, i.e., the conductive pillar 311 is a copper pillar. In other implementations, the material of the conductive pillar may be other metal materials, for example, one or more of tin, copper, aluminum, tungsten, cobalt, nickel, titanium, tantalum, titanium nitride and tantalum nitride.

In this implementation, the number of the conductive pillars 311 is plural to improve the electrical connection performance between the conductive pillar 311 and the substrate.

In an example, the step of forming the conductive pillar 311 includes: forming a patterned layer (not shown) on the first redistribution structure 401, a plurality of openings located in the first area being formed in the patterned layer; filling the openings with the conductive pillars 311; and removing the patterned layer.

Referring to FIG. 4, a device chip 201 is provided. The device chip includes a first side 201a and a second side 201b opposite to the first side 201a.

The device chip 201 is used for electrical connection to the substrate, so as to form the corresponding packaging structure to enable corresponding functions.

In this implementation, the first side 201a is a front side of the chip, and the second side 201b is a back side of the chip.

In this implementation, the front side of the chip is a side facing the device in the chip, and the back side of the chip is a side facing away from the device in the chip.

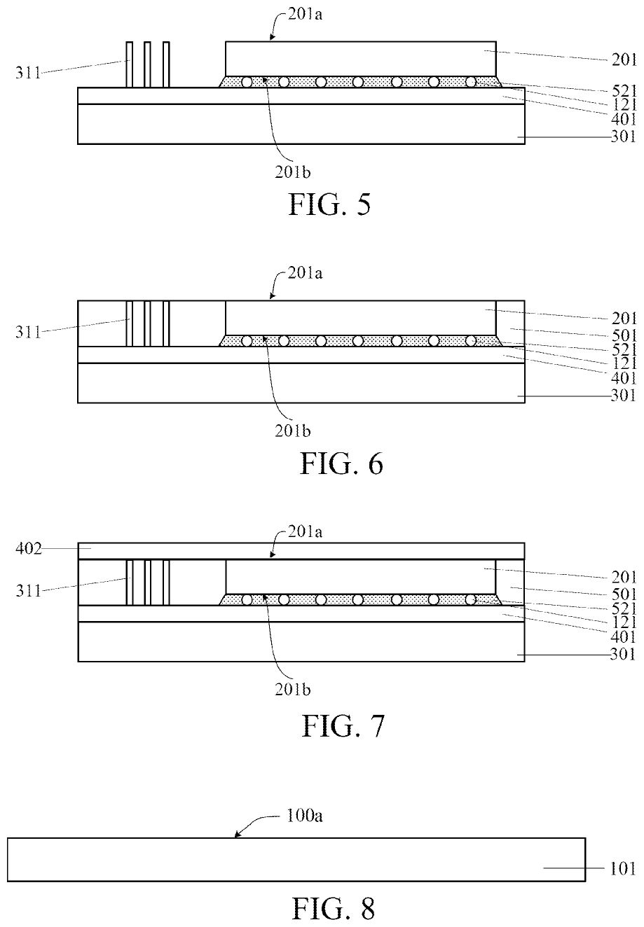

Referring to FIG. 5, the second side 201b of the device chip 201 is bonded to the first redistribution structure 401 in the second area, and the device chip 201 is electrically connected to the first redistribution structure 401.

The second side 201b of the device chip 201 is bonded to the first redistribution structure 401 in the second area so as to enable electrical connection between the second side 201b of the device chip 201 and the first redistribution structure 401, and thereby, electrical connection between the second side 201b of the device chip 201 and an external circuit (e.g., substrate) can be enabled through the conductive pillar 311 and the first redistribution structure 401.

In this implementation, the second side 201b is a back side of the chip, thereby enabling electrical connection between the back side of the device chip 201 and the substrate. The back side of the chip is a side facing away from the device in the chip.

In this implementation, after bonding the second side 201b of the device chip 201 to the redistribution structure 401 in the second area, the first side 201a of the device chip 201 faces away from the carrier 301 so as to expose the first side 201a of the device chip 201, thereby facilitating subsequent bonding between the first side 201a of the device chip 201 and the substrate.

In an example, after forming the conductive pillar 311, the second side 201b of the device chip 201 is boned to the first redistribution structure 401 in the second area, thereby preventing the process of forming the conductive pillar 311 from affecting the device chip 201. In other implementations, the process sequence of forming the conductive pillar and bonding the second side of the device chip to the first redistribution structure in the second area may be changed based on actual process demands.

In an example, the step of bonding the second side 201b of the device chip 201 to the first redistribution structure 401 in the second area includes: forming a first conductive bump 121 on any one or both of the first redistribution structure 401 in the second area and the second side 201b of the device chip 201; and bonding the second side 201b of the device chip 201 to the first redistribution structure 401 in the second area through the first conductive bump 121, the first conductive bump 121 electrically connecting the device chip 201 to the first redistribution structure 401.

The first conductive bump 121 is used for enabling electrical connection between the first redistribution structure 401 and the device chip 201.

In this implementation, a material of the first conductive bump 121 includes one or more of tin, copper, aluminum, tungsten, cobalt, nickel, titanium, tantalum, titanium nitride and tantalum nitride. In an example, the material of the first conductive bump 121 is tin.

For example, the first conductive bump 121 may be C4 (Controlled Collapse Chip Connection), and has excellent electrical properties and thermal characteristics. Moreover, in a case of the same pitch between the first conductive bumps 121, the I/O number can be very high, and not limited by the size of the redistribution structure. Besides, the first conductive bump is suitable for mass production, and the size and weight are greatly reduced.

In other implementations, the first conductive bump may be a uBump.

Still referring to FIG. 5, after bonding the second side 201b of the device chip 201 to the first redistribution structure 401 in the second area and before bonding the first side 201a of the device chip 201 and the conductive pillar 311 to the bonding surface, the packaging method further includes: filling a first sealing layer 521 in a gap between the adjacent first conductive bumps 121, the first sealing layer 521 covering the first conductive bump 121.

The first sealing layer 521 is used for enabling sealing between the device chip 201 and the first redistribution structure 401, and also used for sealing the first conductive bump 121. In an example, the first sealing layer 521 is an underfill.

Referring to FIG. 6, the packaging method further includes: forming, after forming the conductive pillar 311 on the first redistribution structure 401 in the first area and bonding the second side 201b of the device chip 201 to the first redistribution structure 401 in the second area and before bonding the first side 201a of the device chip 201 and the conductive pillar 311 to the bonding surface, a packaging layer 501 covering side walls of the device chip 201 and the conductive pillar 311 on the first redistribution structure 401.

The first packaging layer 501 is used for protecting structures of the device chip 201, the conductive pillar 311 and the first redistribution structure 401, and also plays a sealing role to isolate the device chip 201, the conductive pillar 311 and the first redistribution structure 401 from an external environment.

In this implementation, a material of the packaging layer 501 is a molding material, for example, epoxy resin. The epoxy resin has the advantages of low shrinkage, good binding property, good corrosion resistance, excellent electrical properties, low cost, etc., and is beneficial to improve the packaging effect of the packaging layer 501 on the device chip 201, the conductive pillar 311 and the first redistribution structure 401. In other implementations, the packaging layer may be made of other appropriate packaging materials.

In an example, the packaging layer 501 is formed by a molding process. In other implementations, the packaging layer may also be formed by other appropriate processes based on actual process demands.

Referring to FIG. 7, after forming the conductive pillar 311 on the first redistribution structure 401 in the first area and bonding the second side 201b of the device chip 201 to the first redistribution structure 401 in the second area and before bonding the first side 201a of the device chip 201 and the conductive pillar 311 to the bonding surface, the packaging method further includes: forming a second redistribution structure 402 on the first side 201a of the device chip 201, the second redistribution structure 402 being electrically connected to the device chip 201 and the conductive pillar 311.

Specifically, the second redistribution structure 402 is located on the first side 201a of the device chip 201, the side of the conductive pillar 311 facing away from the carrier 301, and the side of the packaging layer 501 facing away from the carrier 301, thereby facilitating subsequent electrical connection between the first side 201a of the device chip 201 and the substrate and electrical connection between the conductive pillar 311 and the substrate.

The second redistribution structure 402 is used for enabling electrical connection between the device chip 201, the conductive pillar 311 and an external circuit, and also used for redistributing interconnection positions of the device chip 201 and the conductive pillar 311 with the outside.

In this implementation, the second redistribution structure 402 includes one or more second redistribution layers. In this implementation, the second redistribution structure 402 including one redistribution layer will be described In an example.

In this implementation, a material of the second redistribution structure 402 is a metal material, for example, one or more of copper, aluminum, tungsten, cobalt, nickel, titanium, tantalum, titanium nitride and tantalum nitride.

In other implementations, the second redistribution structure may also be omitted in the packaging structure based on actual process demands.

Referring to FIG. 8, a substrate 101 is provided. The substrate includes a bonding surface 101a.

The substrate 101 is used for enabling bonding to the device chip 201 and bonding to the conductive pillar 311 so as to enable packaging integration and electrical integration of the device chip 201, the conductive pillar 311 and the substrate 101. The substrate 101 is also used for providing a process operation basis for enabling bonding to the device chip 201 and bonding to the conductive pillar 311.

Specifically, the bonding surface 101a of the substrate 101 is a process operation platform.

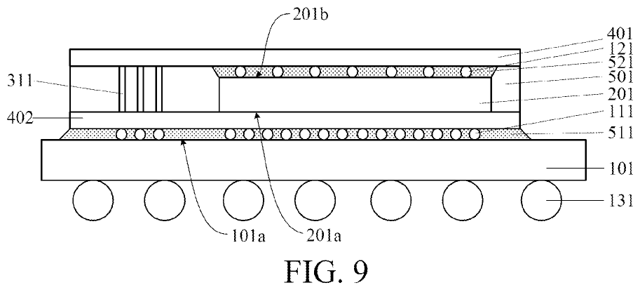

In this implementation, the substrate 101 is a PCB (printed circuit board). Referring to FIG. 9, after forming the conductive pillar 311 on the first redistribution structure 401 in the first area and bonding the second side 201b of the device chip 201 to the first redistribution structure 401 in the second area, the first side 201a of the device chip 201 and the conductive pillar 311 are bonded to the bonding surface 101a. The device chip 201 is electrically connected to the substrate 101, and the conductive pillar 311 is electrically connected to the substrate 101.

In this implementation, the first side 201a of the device chip 201 is bonded to the bonding surface 101a to enable electrical connection between the first side 201a of the device chip 201 and the substrate 101, the device chip 201 is electrically connected to the conductive pillar 311 through the first redistribution structure 401 located on the second side 201b of the device chip 201, and the conductive pillar 311 is electrically connected to the substrate 101 so as to enable electrical connection between the second side 201b of the device chip 201 and the substrate 101, so that the first side 201a and the second side 201b of the device chip 201 opposite to each other can both be electrically connected to the substrate 101, and accordingly the first side 201a and the second side 201b of the device chip 201 can both be electrically connected to an external circuit through the substrate 101, thereby improving the integration level of the packaging structure.

During the actual process, this implementation is particularly applicable to the case where a buried power rail (BPR) structure and a power delivery network (PDN) structure are used, which has high requirements for chip size and integration level.

In an example, the first side 201a of the device chip 201 is bonded to the bonding surface 101a to enable signal communication between the first side 201a of the device chip 201 and the substrate 101. The device chip 201 is electrically connected to the conductive pillar 311 through the first redistribution structure 401 located on the second side 201b of the device chip 201, and the conductive pillar 311 is electrically connected to the substrate 101 so as to enable electrical connection between the second side 201b of the device chip 201 and the substrate 101, thereby enabling power supply to the device chip 201 through the substrate 101.

In this implementation, after the first redistribution structure 401 is temporarily bonded to the carrier 301, the second side 201b of the device chip 201 and the conductive pillar 311 are bonded to the first redistribution structure 401, and then the first side 201a of the device chip 201 and the conductive pillar 311 are bonded to the bonding surface 101a of the substrate 101, so that the first redistribution structure 401, the device chip 201 and the conductive pillar 311 are fixed as an integral structure first and then the integral structure is bonded to the substrate 101, which is beneficial to improve the packaging effect.

In an example, the step of bonding the first side 201a of the device chip 201 and the conductive pillar 311 to the bonding surface 101a of the substrate 101 includes: forming a second conductive bump 111 on the first side 201a of the device chip 201 and the conductive pillar 311, and/or, on the bonding surface 101a of the substrate 101; and enabling bonding of the device chip 201 to the substrate 101 and bonding of the conductive pillar 311 to the substrate 101 through the second conductive bump 111, the second conductive bump 111 electrically connecting the device chip 201 to the substrate 101 and electrically connecting the conductive pillar 311 to the substrate 101.

The second conductive bump 111 is used for enabling electrical connection between the substrate 101 and the device chip 201 and enabling electrical connection between the conductive pillar 311 and the substrate 101.

In an example, the second conductive bump 111 is located between the second redistribution structure 402 and the substrate 101, which is beneficial to improve the density of the second conductive bumps 111, thereby improving the interconnection density between the device chip 201 and the substrate 101 and the interconnection density between the conductive pillar 311 and the substrate 101. Accordingly, the second conductive bump 111 is used for enabling electrical connection between the second redistribution structure 402 and the substrate 101.

In this implementation, a material of the second conductive bump 111 includes one or more of tin, copper, aluminum, tungsten, cobalt, nickel, titanium, tantalum, titanium nitride and tantalum nitride. In an example, the material of the second conductive bump 111 is tin.

For example, the second conductive bump 111 may be C4 (Controlled Collapse Chip Connection), and has excellent electrical properties and thermal characteristics. Moreover, in a case of the same pitch between the second conductive bumps 111, the I/O number can be very high, and not limited by the size of the redistribution structure. Besides, the second conductive bump is suitable for mass production, and the size and weight are greatly reduced. In other implementations, the second conductive bump may be a uBump.

Still referring to FIG. 9, after bonding the first side 201a of the device chip 201 and the conductive pillar 311 to the bonding surface 101a, the packaging method further includes: filling a second sealing layer 511 in a gap between the adjacent second conductive bumps 111, the second sealing layer 511 covering the second conductive bump 111.

The second sealing layer 511 is used for enabling sealing between the device chip 201 and the substrate 101 and sealing between the conductive pillar 311 and the substrate 101, and also used for sealing the second conductive bump 111.

More specifically, in this implementation, the second sealing layer 511 is used for enabling sealing between the second redistribution structure 402 and the substrate 101, and also used for sealing the second conductive bump 111.

In this implementation, the second sealing layer 511 is an underfill.

Still referring to FIG. 9, the packaging method further includes: removing, after bonding the first side 201a of the device chip 201 and the conductive pillar 311 to the bonding surface 101a, the carrier 301.

Specifically, the carrier 301 is removed by debonding.

Still referring to FIG. 9, in this implementation, after bonding the first side 201a of the device chip 201 and the conductive pillar 311 to the bonding surface 101a, the packaging method further includes: forming a third conductive bump 131 on a surface of the substrate 101 facing away from the bonding surface 101a, the third conductive bump 131 being used for enabling electrical connection between the packaging structure and an external circuit.

The electrical connection between the packaging structure and the external circuit is enabled through the third conductive bump 131, so that the front side and the back side of the device chip 201 are both electrically connected to the external circuit.

In this implementation, a material of the third conductive bump 131 includes one or more of tin, copper, aluminum, tungsten, cobalt, nickel, titanium, tantalum, titanium nitride and tantalum nitride. In an example, the material of the third conductive bump 131 is tin.

For example, the third conductive bump 131 may be C4 (Controlled Collapse Chip Connection), and has excellent electrical properties and thermal characteristics. Moreover, in a case of the same pitch between the third conductive bumps 131, the I/O number can be very high, and not limited by the size of the redistribution structure. Besides, the third conductive bump is suitable for mass production, and the size and weight are greatly reduced.

In other implementations, the third conductive bump may be a ball grid array (BGA) structure.

Although the disclosure has been described above, the disclosure is not limited thereto. Any person skilled in the art can make various changes and modifications without departing from the spirit and scope of the disclosure, so the scope of protection of the disclosure shall be subject to the scope defined by the claims.

What is claimed is:

1. A packaging structure, comprising:
a substrate, comprising a bonding surface;
a device chip, comprising a first side and a second side opposite to the first side, the first side being bonded to the bonding surface and electrically connected to the substrate;
a conductive pillar, bonded to the bonding surface at a side of the device chip and electrically connected to the substrate; and
a first redistribution structure, located on the second side of the device chip and a side of the conductive pillar facing away from the bonding surface, the first redistribution structure being electrically connected to the second side of the device chip and the conductive pillar.

2. The packaging structure according to claim 1, wherein the first side is a front side of the device chip, and the second side is a back side of the device chip.

3. The packaging structure according to claim 1, wherein the packaging structure further comprises:
a packaging layer, located on the first redistribution structure and covering the device chip and side walls of the conductive pillar.

4. The packaging structure according to claim 1, wherein the packaging structure further comprises:
first conductive bumps, located between the device chip and the first redistribution structure and electrically connecting the device chip to the first redistribution structure.

5. The packaging structure according to claim 4, wherein the packaging structure further comprises:
a first sealing layer, filled in a gap between adjacent first conductive bumps and covering the first conductive bumps.

6. The packaging structure according to claim 1, wherein the packaging structure further comprises:
second conductive bumps, located between the device chip and the substrate and between the conductive pillar and the substrate, electrically connecting the device chip to the substrate and electrically connecting the conductive pillar to the substrate.

7. The packaging structure according to claim 1, wherein the packaging structure further comprises:
a second redistribution structure, located on the first side of the device chip and a side of the conductive pillar facing the substrate, the second redistribution structure being electrically connected to the device chip and the conductive pillar.

8. The packaging structure according to claim 6, wherein the packaging structure further comprises:
a second sealing layer, filled in a gap between adjacent second conductive bumps and covering the second conductive bumps.

9. The packaging structure according to claim 1, wherein the packaging structure further comprises:
a third conductive bump, located on a surface of the substrate facing away from the bonding surface, the third conductive bump being for enabling electrical connection between the packaging structure and an external circuit.

10. The packaging structure according to claim 7, wherein the first redistribution structure comprises one or more first redistribution layers, and the second redistribution structure comprises one or more second redistribution layers.

11. A packaging method for a packaging structure, comprising:
providing a carrier;
forming a first redistribution structure on the carrier, the first redistribution structure comprising a first area and a second area;
forming a conductive pillar on the first redistribution structure in the first area, the conductive pillar being electrically connected to the first redistribution structure;
providing a device chip, comprising a first side and a second side opposite to the first side;
bonding the second side of the device chip to the first redistribution structure in the second area, the device chip being electrically connected to the first redistribution structure;
providing a substrate comprising a bonding surface; and
after forming the conductive pillar on the first redistribution structure in the first area and bonding the second side of the device chip to the first redistribution structure in the second area, bonding the first side of the device chip and the conductive pillar to the bonding surface, the device chip being electrically connected to the substrate, and the conductive pillar being electrically connected to the substrate.

12. The packaging method according to claim 11, wherein in the step of providing the device chip, the first side is a front side of the device chip, and the second side is a back side of the device chip.

13. The packaging method according to claim 11, wherein the packaging method further comprises:
after forming the conductive pillar on the first redistribution structure in the first area and bonding the second side of the device chip to the first redistribution structure in the second area and before bonding the first side of the device chip and the conductive pillar to the bonding surface, forming a packaging layer covering side walls of the device chip and the conductive pillar on the first redistribution structure.

14. The packaging method according to claim 11, wherein the step of bonding the second side of the device chip to the first redistribution structure in the second area comprises:
forming first conductive bumps on the first redistribution structure in the second area or the second side of the device chip; and
bonding the second side of the device chip to the first redistribution structure in the second area through the first conductive bumps, the first conductive bumps electrically connecting the device chip to the first redistribution structure.

15. The packaging method according to claim 14, wherein the packaging method further comprises:
after bonding the second side of the device chip to the first redistribution structure in the second area and before bonding the first side of the device chip and the conductive pillar to the bonding surface, filling a first sealing layer in a gap between adjacent first conductive bumps, the first sealing layer covering the first conductive bumps.

16. The packaging method according to claim 11, wherein the step of bonding the first side of the device chip and the conductive pillar to the bonding surface comprises:
forming second conductive bumps on the first side of the device chip and the conductive pillar, or on the bonding surface of the substrate; and
enabling bonding of the device chip to the substrate and bonding of the conductive pillar to the substrate through the second conductive bumps, the second conductive bumps electrically connecting the device chip to the substrate and electrically connecting the conductive pillar to the substrate.

17. The packaging method according to claim 11, wherein the packaging method further comprises:
after forming the conductive pillar on the first redistribution structure in the first area and bonding the second side of the device chip to the first redistribution structure in the second area and before bonding the first side of the device chip and the conductive pillar to the bonding surface, forming a second redistribution structure on the first side of the device chip, the second redistribution structure being electrically connected to the device chip and the conductive pillar.

18. The packaging method according to claim 16, wherein the packaging method further comprises:
after bonding the first side of the device chip and the conductive pillar to the bonding surface, filling a second sealing layer in a gap between adjacent second conductive bumps, the second sealing layer covering the second conductive bumps.

19. The packaging method according to claim 11, wherein the packaging method further comprises:
after bonding the first side of the device chip and the conductive pillar to the bonding surface, removing the carrier.

20. The packaging method according to claim 11, wherein after bonding the first side of the device chip and the conductive pillar to the bonding surface, the packaging method further comprises:
forming a third conductive bump on a surface of the substrate facing away from the bonding surface, the third conductive bump being for enabling electrical connection between the packaging structure and an external circuit.
